(19) United States
(12) Patent Application Publication
(10) Pub. No.: US 2017/0301824 A1
(43) Pub. Date: Oct. 19, 2017

(54) OPTICAL DEVICE AND METHOD FOR ITS FABRICATION

(71) Applicant: Kabushiki Kaisha Toshiba, Minato-ku (JP)

(72) Inventors: Joanna Krystyna SKIBA-SZYMANSKA, Cambridge (GB); Tina MUELLER, Cambridge (GB); Jan HUWER, Cambridge (GB); Richard Mark STEVENSON, Cambridge (GB); Andrew James SHIELDS, Cambridge (GB)

(73) Assignee: Kabushiki Kaisha Toshiba, Minato-ku (JP)

(21) Appl. No.: 15/442,962

(22) Filed: Feb. 27, 2017

(30) Foreign Application Priority Data
Apr. 19, 2016 (GB) 1606833.0

(51) Int. Cl. H01L 33/06; H01L 33/10; H01L 33/30; H01L 33/00; B82Y 40/00; B82Y 20/00

(52) U.S. Cl. CPC H01L 33/06; H01L 33/30; H01L 33/0062; H01L 33/10; Y10S 977/818; Y10S 977/774; B82Y 20/00; B82Y 40/00; Y10S 977/819; Y10S 977/891; Y10S 977/95; H01L 2933/0083

(57) ABSTRACT

An optical device comprising:
a quantum dot, said quantum dot comprising InAs and adapted to emit radiation in the wavelength range from 1200 nm to 2000 nm;
a supporting layer supporting said quantum dot, said supporting layer being lattice matched to InP; and
wherein the longest dimension of the base of the quantum dot provided parallel to the supporting layer is within 20% of the shortest dimension of the base provided parallel to the supporting layer.

### FIELD

Embodiments described herein relate generally to the field of optical devices, for example, photon sources, and methods for their fabrication.

### BACKGROUND

Optical devices such as photon sources have applications in many fields such as quantum communication, quantum computing and quantum sensing. Photon sources based on quantum dots can be operated to output single photons or pairs of entangled photons. There is a continuing need to improve the performance of these devices.

### BRIEF DESCRIPTION OF THE FIGURES

Devices and methods in accordance with non-limiting embodiments will now be described with reference to the accompanying figures in which:

FIG. 1A shows a cross section of an InAs quantum dot formed on a GaAs substrate using a Stranski-Krastanov growth mode;

FIG. 1B shows a plan view of an InAs quantum dot formed on a GaAs substrate using the Stranski-Krastanov growth mode;

FIG. 1C shows a cross section of an InAs quantum dot formed on a GaAs substrate using a droplet epitaxy growth mode;

FIG. 1D shows a plan view of an InAs quantum dot formed on a GaAs substrate using the droplet epitaxy growth mode;

FIG. 1E shows a cross section of an InAs quantum dot formed on an InP substrate using a droplet epitaxy growth mode;

FIG. 1F shows a plan view of an InAs quantum dot formed on an InP substrate using the droplet epitaxy growth mode;

FIG. 1G shows a cross section of an InAs quantum dot formed on an InP substrate using a Stranski-Krastanov growth mode;

FIG. 1H shows a plan view of an InAs quantum dot formed on an InP substrate using the Stranski-Krastanov growth mode;

FIG. 2A shows In and As deposited onto a GaAs surface simultaneously, in a single step;

FIG. 2B shows a thin layer of InAs, referred to as a wetting layer, formed overlying and in contact with the GaAs surface;

FIG. 2C shows InAs quantum dots formed by strain relaxation in the InAs wetting layer;

FIG. 3A shows In droplets formed on the GaAs surface;

FIG. 3B shows As being deposited;

FIG. 3C shows InAs quantum dots formed through reaction of the As with the In droplets;

FIG. 4 is a flow chart illustrating a droplet growth mode method that can be used in a method of fabricating an optical device in accordance with an embodiment;

FIG. 5A is an SEM micrograph of In droplets on an InP layer prior to the crystallisation step;

FIG. 5B is an SEM micrograph an AFM image of In droplets on an InP layer after As deposition and the crystallisation step;

FIG. 5C is an AFM image of In droplets on an InP layer prior to the crystallisation step;

FIG. 5D is an AFM image of In droplets on an InP layer after As deposition and the crystallisation step;

FIG. 5E is an AFM image of Stranski-Krastanov growth mode quantum dots shown with a scale bar of 200 nm;

FIG. 5F is an AFM image of droplet growth quantum dots shown at the same scale of those of FIG. 5E;

FIG. 5G is an AFM image of Stranski-Krastanov growth mode quantum dots shown with a scale bar of 400 nm;

FIG. 5H is an AFM image of droplet growth quantum dots shown at the same scale of those of FIG. 5G;

FIG. 6A is a layer structure of an InAs quantum dot in a GaAs cavity;

FIG. 6B is a plot of the corresponding refractive index of the structure of FIG. 6A;

FIG. 6C is a plot of the corresponding electric field of FIG. 6A;

FIG. 7A is a layer structure of an InAs quantum dot in an InP cavity;

FIG. 7B is a plot of the corresponding refractive index of the structure of FIG. 7A;

FIG. 7C is a plot of the corresponding electric field of FIG. 7A;

FIG. 8 is a schematic illustration of an optical device comprising an optically excited cavity in accordance with an embodiment;

FIG. 9A is a schematic illustration of an optical device configured as an LED with an asymmetric optical cavity comprising an optically excited cavity in accordance with an embodiment;

FIG. 9B is the optical device of FIG. 9A with a power supply and filter;

FIG. 10 is a schematic illustration of an optical device configured as an LED with a symmetric optical cavity comprising an optically excited cavity in accordance with an embodiment;

FIG. 11A is a cross section of a photonic cavity device based on the device of FIG. 8;

FIG. 11B is the corresponding plan view of the photonic cavity device based on the device of FIG. 8;

FIG. 12 is a cross section of a photonic cavity device based on the device of FIG. 9;

FIG. 13 is a schematic of a device in accordance with an embodiment of the present invention where the quantum dots are formed in depressions provided in surface of an InP layer;

FIG. 14A is a histogram showing the population of quantum dots and their fine structure spitting for InAs quantum dots formed via the Stranski-Krastanov growth technique;

FIG. 14B is a histogram showing the population of quantum dots and their fine structure spitting for InAs quantum dots formed via the droplet epitaxy growth technique;

FIG. 14C is a plot of the fine structure splitting energy against wavelength for both of the types of quantum dots in FIGS. 14A and 14B;

FIG. 15 shows the optical response of InAs DQDs on InP(100);

FIG. 16 shows the EL spectrum of the InAs DQD on InP (100), where (a) shows power dependence and (b) shows bias dependence; and

FIG. 17A shows the optical response of InAs DQDs on InP(100); and

FIG. 17B shows the autocorrelation function measured for the XX line from InAs DQDs on InP(100) emitting at 1550 nm as shown in FIG. 17A.

### DETAILED DESCRIPTION

In an embodiment an optical device is provided comprising:
a quantum dot, said quantum dot comprising InAs and adapted to emit radiation in the wavelength range from 1200 nm to 2000 nm;
a supporting layer supporting said quantum dot, said supporting layer being lattice matched to InP; and
wherein the longest dimension of the base of the quantum dot provided parallel to the supporting layer is within 20% of the shortest dimension of the base provided parallel to the supporting layer.

In the above optical device, the quantum dot has a splitting of 50 μeV or less. With such a low fine structure splitting, the optical device can function as an entangled photon source.

In a further embodiment, the quantum dot has fine structure splitting of 20 μeV or less, in yet further embodiments, the quantum dot has fine structure splitting of 10 μeV or less.

The above quantum dot operates in the telecom wavelength bands of 1.3 μm and 1.55 μm. The quantum dot is also symmetric and therefore had low fine structure splitting. This allows the quantum dot to be a candidate for an entangled photon source, where the two entangled photons are produced due to decay of a bi-exciton.

Using a quantum dot with low fine structure splitting allows the two photons being produced through indistinguishable decay paths, making them candidates for entanglement.

The quantum dots emit in the range from 1200 nm to 2000 nm, this also covers the telecoms U band at 1675 nm. In some embodiments, the quantum dots emits in the range from 1200 nm to 1680 nm, in other embodiments, the quantum dots emit in the range from 1200 nm to 1625 nm.

In an embodiment, the optical device comprises a plurality of quantum dots, and wherein the density of the quantum dots on the wetting layer is less than 1×10⁹cm⁻². By forming the quantum dots with a low density, it is possible to fabricate a device with just a single quantum dot in the cavity.

The optical device may comprise a [100] oriented substrate.

In some embodiments, the device further comprises a wetting layer provided overlying the supporting layer. In one embodiment, the wetting layer is formed due to As exchange with P, here, the supporting layer comprises InP or InGaAsP and the wetting layer will comprise InAsP.

However, in other embodiments, no wetting layer is formed. For example, the quantum dots may be formed of InAs and the supporting layer comprises AlInAs or AlInGaAs.

Where a wetting layer is present, the device may further comprise a filter, said filter being adapted to filter out radiation emitted by a wetting layer. Typically, the wetting layer will emit in the range from 1050 nm to 1250 nm. The filter will be selected to filter out the wetting layer, but not the photons from the quantum dots.

In further embodiments, the optical device further comprises an upper layer provided overlying the quantum dot and wetting layer if present.

The optical device may comprise a plurality of quantum dots, and wherein the density of the quantum dots is less than 10⁹cm⁻². This low density of quantum dots makes it easier to isolate the output from one quantum dot.

The optical device may be optically or electrically activated. In one embodiment, an electrically activated optical device is configured as an LED wherein the device comprises an n doped region provided on one side of the quantum dot and a p doped region on the other side of the quantum dot.

The optical device may comprise a cavity region, said cavity region adapted to accommodate said quantum dot and preferentially reflect radiation emitted from said quantum dot within said cavity. The cavity may be an asymmetric cavity comprising a single distributed Bragg reflector provided on one side of the cavity.

The cavity comprises an intrinsic region and a p-doped region is provided on one side of the quantum dot, the thickness of the layers between the quantum dot and the p-doped region being greater than the distance over which the p-type dopants diffuse into the intrinsic region during the growth of the device. Therefore, in one example, the thickness of the layers between the quantum dot and the p-doped region is greater than the distance over which the p-type dopants diffuse at 630° C.

The device may be fabricated using MOVPE or MBE. When using MOVPE, it is possible to predetermine the position of quantum dots by patterning the support layer, for example, with a pit, depression or the like and the quantum dot is positioned at the pit in the pattern.

Embodiments of the present invention may also provide a method of fabricating an optical device, the method comprising:
forming a support layer, said support layer being lattice matched to InP;
forming a layer of In, said amount of In being controlled to allow the formation of In droplets;
growing As over said In droplets and crystallising said droplets to form InAs dots;
wherein the formation of the In droplets and crystallisation is controlled to produce quantum dots adapted to emit radiation in the wavelength range from 1200 nm to 2000 nm and wherein the longest dimension of the base of the quantum dot provided parallel to the supporting layer is within 20% of the shortest dimension of the base provided parallel to the supporting layer.
The above method allows the formation of symmetric dots due to the inherent symmetry of indium droplets. The Indium amount and Indium deposition temperature will determine the dot density
Crystallisation process relies on supplying As to the dots and raising the growth temperature at the same time. At high temperatures the adatom migration is more probable therefore the possibility of elongation of the dots. In an embodiment, the symmetric shape of the dots is preserved by ramping the crystallisation temperature to 500° C. followed by immediate capping of the dots.

In a method in accordance with an embodiment, the layers are formed using MOVPE or MBE.

The optical device may be formed using MOVPE and 2M L of In is deposited to form the droplets.

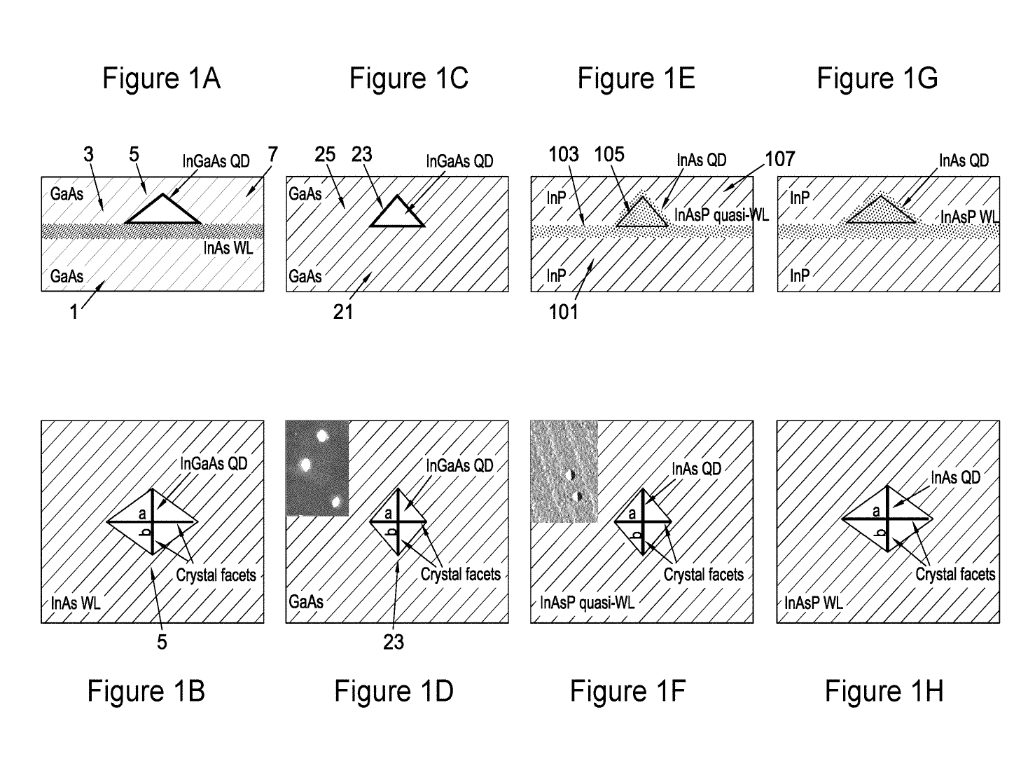

FIG. 1A shows a side view of quantum dot fabricated using a Stranski-Krastanov technique and FIG. 1B is a plan view of the quantum dot of FIG. 1A. The dots are formed as an effect of strain accommodation in InAs wetting layer (WL) as it gets thicker. The resulting dots are elongated along a privileged crystallographic direction.

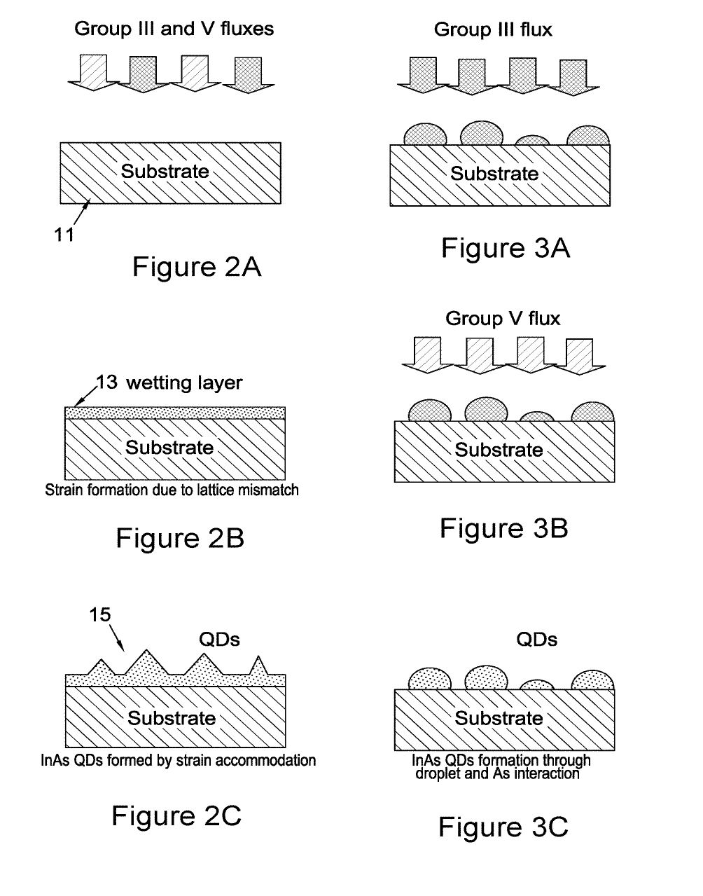

In FIG. 1A there is a GaAs lower or support layer 1. On top of this layer is an InAs wetting layer 3. Next, a quantum dot 5 is provided comprising InGaAs. Overlying and in contact with the quantum dot 5 is upper GaAs layer 7. The fabrication of this quantum dot 5 will be described with reference to FIG. 2A.

FIG. 2 is a schematic illustration of a Stranski-Krastanov growth mode technique for the formation of quantum dots. For Stranski-Krastanov QDs both In and As fluxes are supplied simultaneously, forming a strained wetting layer which evolves into QDs as the thickness increases.

In FIG. 2A, In and As are deposited onto a GaAs surface 11. The In and As are deposited simultaneously, in a single step.

In FIG. 2B, it is shown that a thin layer of InAs, referred to as the wetting layer 13, has formed overlying and in contact with the GaAs surface. Strain formation occurs in the wetting layer due to lattice mismatch between the InAs wetting layer and the GaAs surface.

InAs quantum dots (QDs) 15 are formed by strain relaxation in the InAs wetting layer 13. The QDs form as “islands” on the wetting layer, as shown in FIG. 2C. The QDs have a pyramidal shaped cross-section, or a truncated pyramid cross-section.

The Stranski-Krastanov technique can be used to form a wetting layer on the (100) surface of a GaAs substrate. QDs form as islands on the wetting layer. The wetting layer has a different lattice constant to the material underlying and in contact with the wetting layer. The wetting layer is a layer out of which the QDs were formed. The thickness of the wetting layer is less than the height of any of the QDs.

Stranski-Krastanov QDs can be formed in structures on GaAs (100) orientated substrates. Such structures will include a wetting layer. For QDs formed by the

Stranski-Krastanov technique, the QDs will have large fine structure splitting i.e. greater than 5 μeV, except for QDs which emit at certain wavelengths, for example −885 nm. The Stranski-Krastanov QDs tend to align to the 110 and 1-10 crystal axes, 90 degrees apart.

Returning to FIG. 1B that shows the plan view of the quantum dot 5. It can be seen the quantum dot is asymmetric due to the Stranski-Krastanov growth technique. This visible asymmetry is also a sign of a large fine structure splitting as discussed above.

FIG. 1C shows a so called droplet quantum dot DQD formed on GaAs (100). The dots are symmetric in shape and do not sit on an InAs wetting layer. In detail, in FIG. 1C, a GaAs support layer 21 is provided. An InGaAs quantum dot 23 is provided on the support layer 21. A GaAs upper layer 25 is provided in contact with the GaAs lower layer 21 and the quantum dot 23.

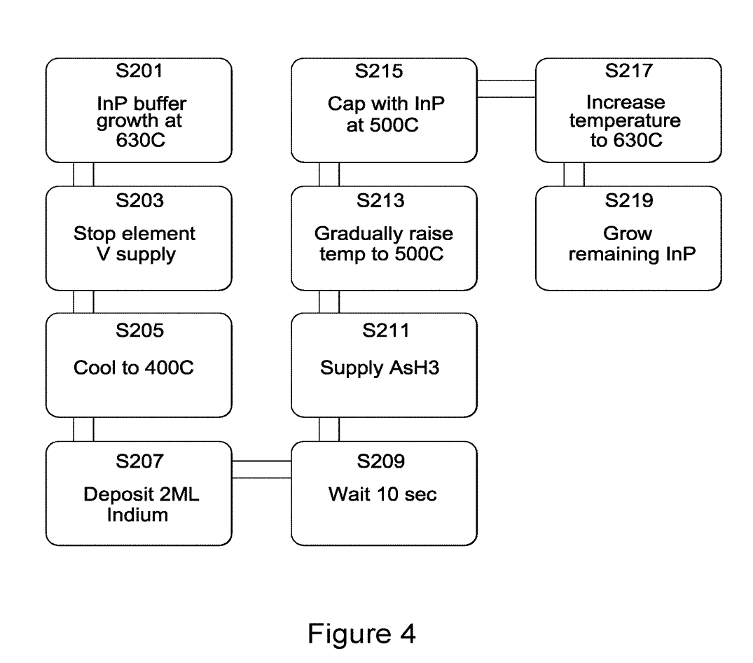

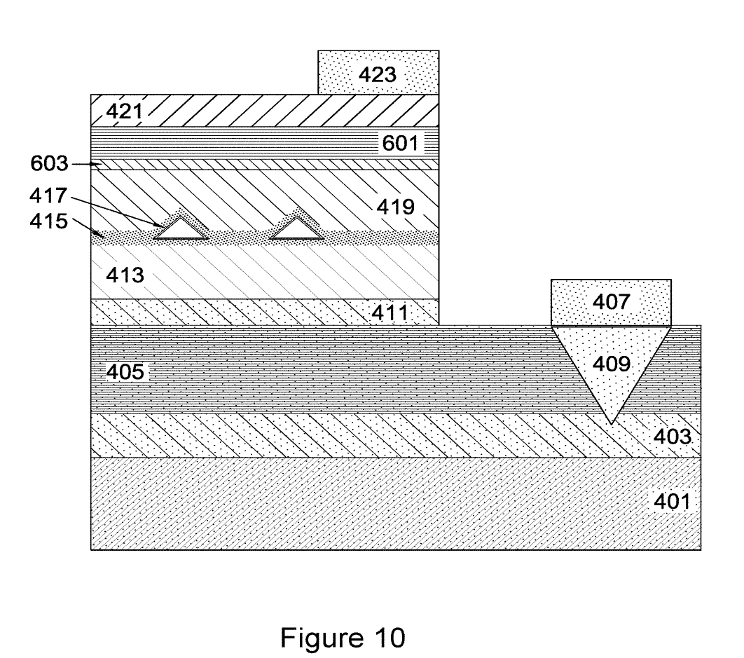

FIG. 1D is a plan view of the quantum dot of FIG. 10. The quantum dot of FIGS. 1C and 1D is fabricated using the method that will be described with reference to FIG. 3.

FIG. 3 is a schematic illustration of a droplet growth mode technique for the formation of quantum dots. The droplet growth mode technique is shown here for InAs QDs formed on a GaAs surface. However, the droplet growth mode technique is not limited to these materials. The droplet growth mode technique can also be used to form InGaAs, AlAs, InP or GaAs quantum dots, for example, on substrate materials such as GaAs or InP, for example.

In FIG. 3A, In droplets are formed on the GaAs surface. Liquid In is deposited onto the GaAs surface. The liquid In forms strain-free droplets on the GaAs surface. The droplets have a rounded cross-section, both in plane and out of plane.

In FIG. 3B, As is deposited. The In droplets react with the As to produce InAs nanocrystals. InAs QDs form through reaction of the As with the In droplets.

In FIG. 3C it can be seen that the InAs QDs formed through reaction of the As with the In droplets are in contact with the GaAs. There is no intermediate wetting layer between the QDs and the GaAs. The quantum dots have a rounded cross-section in the out of plane direction.

Droplet growth mode techniques can be used to form QDs on GaAs (111B) orientated substrates. These QDs have a lower FSS splitting than Stranski-Krastanov QDs.

Returning to the plan view of FIG. 1D, it can be seen that the quantum dot 23 is more symmetric than the quantum dot 15 of FIG. 1B. The distance “a” between one pair of opposite apexes, is approximately the same as the distance “b” between the other paid of opposite apexes.

FIG. 1E shows an Indium droplet quantum dot (DQD) on InP(100) formed using a process as described with reference to FIG. 3. In the DQD of FIG. 1E, the dots are symmetric in shape but have a quasi-wetting layer made of InAsP that was formed during droplet crystallisation process as element As—P exchange process.

In detail, in FIG. 1E, an InP support layer 101 is provided. An InAsP wetting layer 103 is provided overlying the support layer 101. An InAs quantum dot 105 is provided on the wetting layer 103 and an InP upper layer 107 is provided on the InAs quantum dot 105 and the InAsP wetting layer 103. As can be seen in the plan view of FIG. 1F, the quantum dot 105 is symmetric with the distance “a” between one pair of opposite apexes, is approximately the same as the distance “b” between the other paid of opposite apexes.

Although the quantum dots formed by droplet epitaxy on the GaAs substrate do not have a wetting layer, the quantum dots formed by droplet epitaxy on the InP have a wetting layer. This wetting layer is formed during the droplet crystallisation process as element As—P exchange process.

FIGS. 1G and 1H show an InAs quantum dot formed on an InP support layer using the Stranski-Krastanov method. The dots are formed as an effect of strain accommodation in InAsP wetting layer (WL) as it gets thicker. The resulting dots are elongated along a privileged crystallographic direction and suffer from the same issues with large fine splitting structure as for the quantum dot described with reference to FIGS. 1A and 1B.

FIG. 2 shows the Stranski-Krastanov (SK) growth mode for fabricating quantum dots whereas FIG. 3 shows the droplet growth mode. In SK growth mode the substrate is subjected to group III and V fluxes simultaneously resulting in formation of a wetting layer. The strain between the substrate and the dots is rising due to lattice mismatch. In the next step SK QDs are formed as a result of strain accommodation in the wetting layer. In the droplet growth mode the substrate is subjected first to group III flux, that results in formation of metal droplets on the surface. In the next step these droplets are crystallised with group V element resulting in formation of DQDs which are strain-free and therefore symmetric.

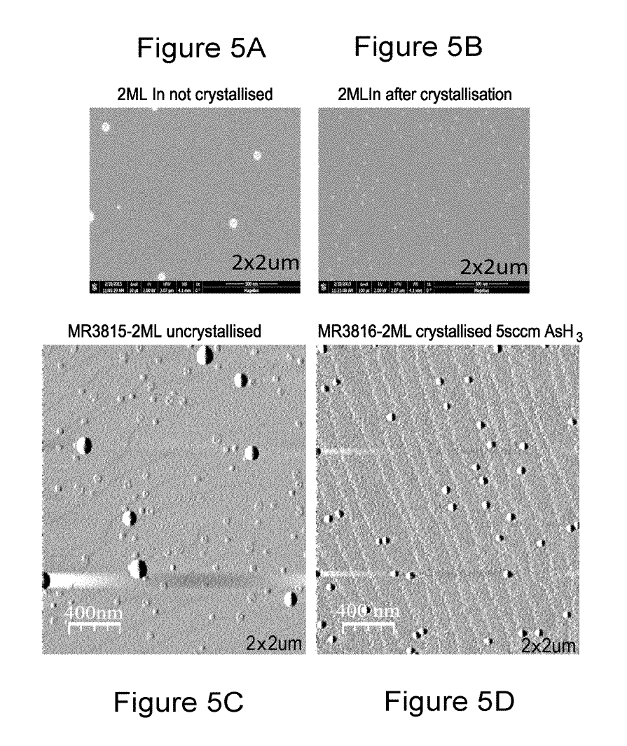

FIG. 4 is a flow chart illustrating a droplet growth mode method that can be used in a method of fabricating an optical device in accordance with an embodiment. The method described is for fabricating InAs QDs formed on an InP substrate.

The method shown in FIG. 4 forms wetting layer free QDs. In and As fluxes are supplied separately. First, liquid Indium forms strain-free droplets on the surface of InP. These droplets are then crystallised using AsH₃. This results in formation of QDs.

An unprocessed substrate may be protected by oxides. The oxides are removed at high temperature in the vacuum chamber before the layered device is grown on the substrate. The oxides are removed by outgassing the InP(100) substrate in an MOVPE reactor. Next an InP buffer layer is grown in step S201 at 630° C. The surface of the substrate after removal of the oxides can be patchy and imperfect.

A buffer layer can be grown to build a reasonably thick layer that spaces all of the important atomic layers away from the substrate/buffer interface. The interface can trap charges that would then interact with QDs or otherwise complicate the device.

The wafer is cooled down to 500° C. under HP3 environment. In step S203, the element V supply (the As supply) is switched off and the substrate and buffer layer is cooled to 400° C. in step S205.

The temperature influences the density of the QDs. In general, the droplet formation temperature and droplet crystallisation temperature may be optimised for a specific quantum dot material, size, and density and therefore may be higher, equal, or lower to each other and the growth temperature of other parts of the device. For some materials, sizes and densities therefore, this step may be omitted.

The Indium cell from which the In is supplied is kept at a high temperature throughout the process. Only the substrate is cooled in this step.

In Step S207 2ML of Indium is deposited on the surface of InP buffer forming Indium droplets. The droplets form metallic blobs.

Next, the process is halted for 10s in step S209. Then, AsH3 gas is switched on in step S211 and the temperature is gradually raised to 500° C. in step S213 in a process referred to as droplet crystallisation. In step S215, at 500° C. the droplets are crystallised and capped with a thin layer of InP. Then the temperature is ramped up to 630C in step S217 to grow remaining InP layers in step S219.

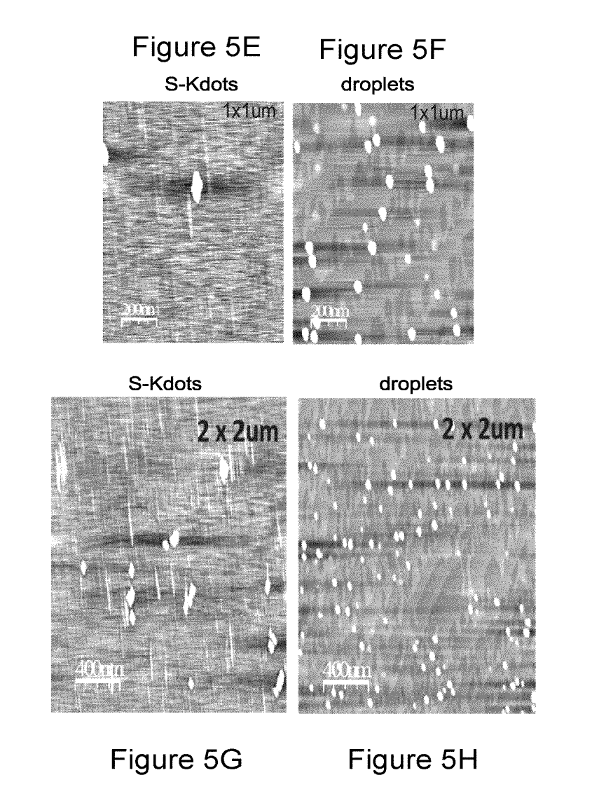

FIG. 5A is an SEM micrograph showing the surface of the structure after indium deposition, but before the crystallisation process. FIG. 5B shows an SEM micrograph of the same surface after crystallisation.

FIG. 5C is an AFM image corresponding to the SEM micrograph of FIG. 5A and FIG. 5D is an AFM image of the SEM micrograph shown in FIG. 5B.

FIGS. 5E and 5G show Stranski-Krastanov growth mode quantum dots formed using the method discussed with relation to FIG. 2. FIGS. 5F and 5H show the quantum dots formed using the droplet growth mode. In FIGS. 5E and 5F, the AFM image has a scale of 200 nm whereas in FIGS. 5G and 5H, the AFM image has a scale of 400 nm.

It can be seen that the Stranski-Krastanov quantum dots have an elongated profile. However, the cross section of the droplet quantum dots in the plane of the growth layer are largely symmetric.

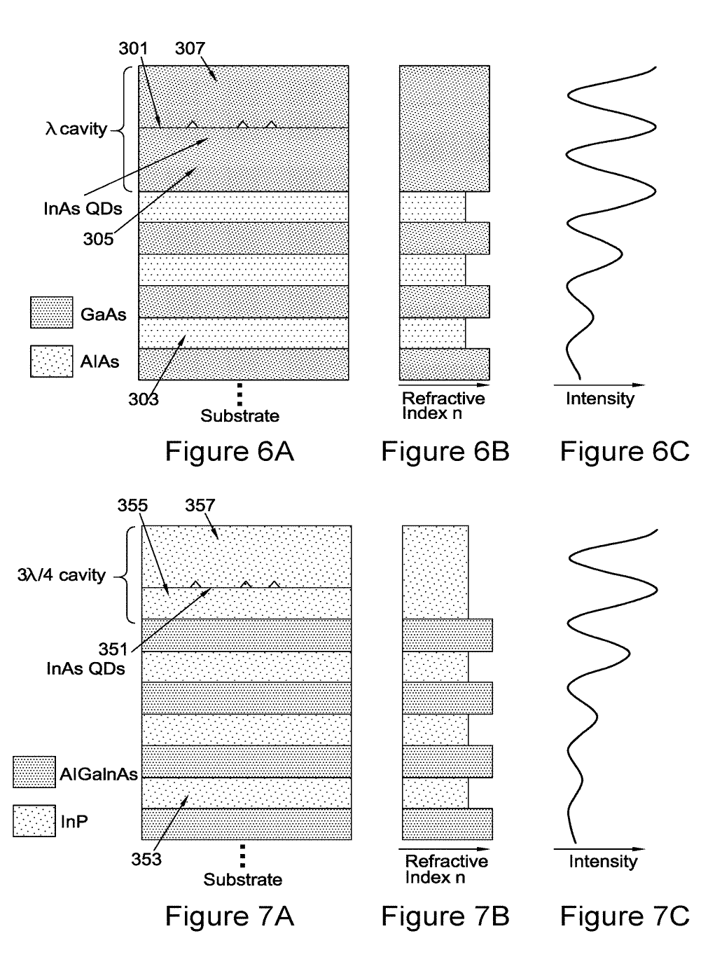

FIG. 6A is a schematic of a layer structure of InAs quantum dots 301 provided in a cavity structure. The cavity structure comprises a plurality of alternating layers of GaAs and AlAs provided as a distributed Bragg reflector (DBR) 303. A lower GaAs layer 305 is provided below the quantum dots 301 and an upper GaAs layer 307 is provided overlying the quantum dots 301 and the lower GaAs layer.

FIG. 6C shows the refractive index n of the layer structure of FIG. 6A. FIG. 6C is a schematic representation of the intensity of the electric field created by the layer structure of FIG. 6A.

It can be seen that in FIG. 6A, the quantum dots sit in the anti-node of the electric field are shown in FIG. 6C. This is located in the centre of the GaAs cavity such that the lower GaAs layer 305 has the same layer thickness as the upper GaAs layer 307.

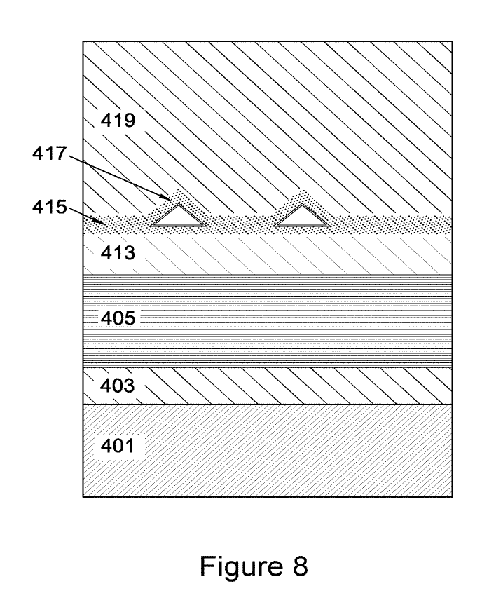

FIG. 7A is a schematic representation of a layer structure of InAs quantum dots 351 provided in a cavity structure. The cavity structure comprises a plurality of alternating layers of InGalnAs and InP provided as a distributed Bragg reflector (DBR) 353. A lower InP layer 355 is provided below the quantum dots 351 and an upper InP layer 357 is provided overlying the quantum dots 351 and the lower GaAs layer.

FIG. 7B shows the refractive index n of the layer structure of FIG. 7A. FIG. 7C is a schematic representation of the intensity of the electric field created by the layer structure of FIG. 7A.

It can be seen that in FIG. 7A, the quantum dots sit in the anti-node of the electric field are shown in FIG. 7C. Due to the difference in the material structure, in the InP cavity of FIG. 7A, the anti-nodes of the cavity are located at (n-½)*(½λ. This is located away from the centre of the InP cavity such that the lower InP layer 355 has a third of the layer thickness of the upper InP layer 357.

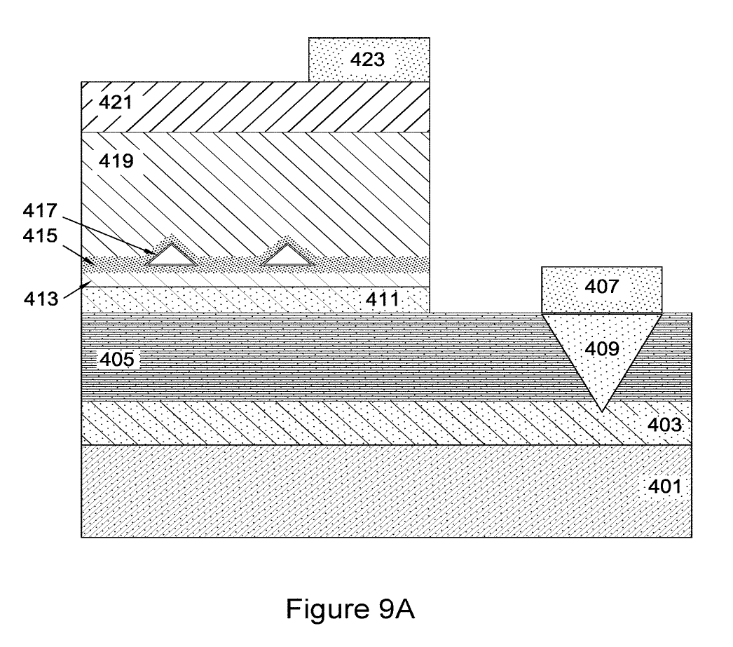

FIG. 8 is a schematic illustration of an optical device in accordance with an embodiment. The device comprises an electrically excited cavity comprising a plurality of quantum dots. The optical device is fabricated using molecular beam epitaxy (MBE).

The device is formed on a substrate 401. In this example, the substrate is InP(100), but other substrates could be used. The device is formed on the (100) surface of the substrate. Growing a planar layered structure on a (100) surface is aided by the atomic configuration of the (100) surface. The (100) surface is an even or uniform, flat surface. The surface is flat on the atomic scale. Growth of layered structures such as DBRs involves growing multiple repetitions of thin material layers. This is aided by growing the layers on an even surface. On a (100) orientated surface, high quality, defect free, monolayer atomic growth can be achieved. This facilitates the creation of mirrors, because the interface between the different InP and AlInGaAs or InP/InGaAsP λ4 layers is atomically flat. Growing high quality mirrors of well-defined thickness, with flat interfaces is possible, resulting in high quality mirror performance.

A 200 nm InP buffer layer 403 is overlying and in contact with the substrate 401. A doped layer 405 is overlying and in contact with the buffer layer 403. A lower distributed Bragg reflector 407 is overlying and in contact with a portion of the doped layer 405. The lower distributed Bragg reflector 407 is an example of a reflecting structure. In one embodiment, it is formed by multiple pairs of high and low refractive index semiconductor, each with optical thickness of λ/4, where λ is the wavelength of the emission from the quantum dots. In one embodiment, the lower distributed Bragg reflector comprises 20 repeats of alternating InP/AlInGaAs or InP/InGaAsP.

A lower InP cavity layer 413 is overlying and in contact with the lower distributed Bragg reflector 405.

A plurality of QDs 417 are grown in the method described with reference to FIG. 3. In this method, a quasi-wetting layer 415 is formed instantly as a result of group V element exchange. The dots (417) are capped with InP (419) forming the remaining thickness of the (2n+1)*¼ lambda cavity, where n is an integer number. When grown on InP substrates, there is very little strain in the quantum dots 417, which allows emission of photons in the telecommunications wavelength band.

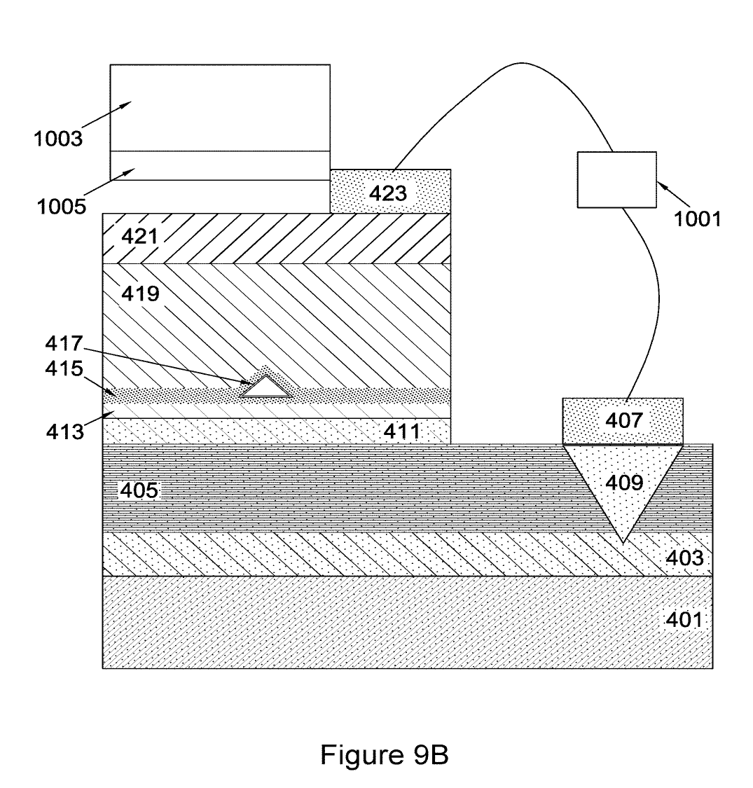

FIG. 9A is a schematic of a layer structure of an asymmetric LED structure using droplet quantum dots described with reference to FIGS. 1E and 1F. As for the structure described with reference to FIG. 8, the cavity structure is grown on InP(100) substrate 401 followed by a 200 nm InP buffer 403 and 20x InP/AlInGaAs or InP/InGaAsP DBR stack 405. To avoid any unnecessary repetition, like reference numerals will be used to denote like features.

Next, the bottom of the cavity layers are formed these are layers 411 and 413. Together, layers 411 and 413 are typically ¼ lambda thick and made of InP. In this example, layer 411 is n-doped and has a thickness of 50 nm.

In the example of FIG. 9A, layers 403, 405 and 411 are doped with Si to firm an n-type InP layers.

As for the structure of FIG. 8, the DQDs 417 are grown on quasi wetting layer 415, formed instantly as a result of group V element exchange. The dots 417 are capped with InP layers 419 and 421 forming the remaining thickness of the (2n+1)*¼ lambda cavity, where n is an integer number. Upper cavity layer 419 is undoped whereas layer 421 is Zn doped InP layer of 50 nm forming p-type InP. However, it should be noted that although the thickness of the p-InP layer 421 is designed to be 50 nm the real layer is thickness is larger due to Zn diffusion into InP at high temperatures.

A metal contact 407 is provided to the n-doped DBR 405. The contact is typically, AuGeNi which is ex-situ annealed to provide low resistance Ohmic contact 409. A p-metal contact 423 which is typically TiAu or CrAu is provided to the p-type upper layer 421.

FIG. 9B shows the optical device of FIG. 9A with power supply 1001 which applies a potential difference between contact 423 and contact 407 and hence across the p-i-n structure and quantum dot 417. By applying the potential across quantum dot 417, it is possible to excite an exciton or even a biexciton in the quantum dot. If a biexciton is excited, the quantum dot 417 is capable of outputting to photons which are entangled in polarisation from decay of this biexciton. This is because the quantum dot is substantially symmetric and therefore has low fine structure splitting. This means that the 2 decay paths of the biexciton are substantially indistinguishable which allows the production of an entangled photon pair.

However, it is also possible to operate the device such that just a single exciton is excited.

FIG. 9B also shows photon collection apparatus 1003. This might be, for example, a fibre-optic cable, lens etc. In FIG. 9B, the surface of the photon collection apparatus which is facing the optical device is provided with a filter 1005.

The quantum dots provide high intensity emission which is accompanied by wetting layer emission. The wetting layer can act as reservoir for re-excitation, influence coherence times and cause multi photon emission at pulsed operation. The filter is adapted to filter out radiation from the wetting layer 415.

The filter 1005 may be provided as part of the optical device itself, as part of the collection optics (shown here) or can be independent component either between the collection optics in the optical device or even provided after the collection optics.

The device described with reference to FIG. 9B is an electrically activated device. The device may also be optically excited where the exciton or biexciton in the quantum dot is excited via optical stimulation. In this situation, the emission from the wetting layer can be avoided by, for example, by resonantly exciting with a laser with energy below that of the wetting layer. The wetting layer acts as a sink for electrical charge.

The wetting layer will produce a signal in photoluminescence measurements. A similar signal could be caused by a second layer of dots, or other 2D feature, e.g. emission from the AlInGaAS part of the DBR. The design of the cavity, wavelength dependent absorption, doping, or other counter-measures can be used to quench the optical wetting layer signal.

FIG. 10 is a schematic of a symmetric LED structure based on InP(100). To avoid unnecessary repetition, like reference numerals will be used to denote like features with those of FIGS. 8 and 9. As for FIG. 9, the cavity structure is grown on InP(100) substrate 401 followed by a 200 nm InP buffer layer 403 and 20x InP/AlInGaAs or InP/InGaAsP DBR stack 405. Layers 403, 405 and 411 are doped with Si to firm an n-type InP layers. Then the bottom of the cavity is grown 411 and 413 which is typically (n-½)*½λ thick and made of InP. Layer 411 is also n-doped and its thickness is 50 nm. The DQDs 417 are grown on quasi wetting layer 415, formed instantly as a result of group V element exchange. The dots 417 are capped with InP 419 and 603 forming the remaining thickness of the n*½ lambda lambda cavity, where n is an integer number.

An upper distributed Bragg reflector 603 is overlying and in contact with the upper cavity layer 4. The DBRs comprise m repeats of InP/AlInGaAs or InP/InGaAsP which are p-doped. The number of repeats, m could vary from 0 to 19. In one example, 3 repeats are used. The larger the number of repeats on the top of the structure, the more difficult it becomes for light to exit the cavity.

Although the thickness of the p-InP is designed to be 50 nm the real layer is thickness is larger due to Zn diffusion into InP at high temperatures. A metal contact 407 is provided to the n-doped DBR 405. The contact is typically, AuGeNi which is ex-situ annealed to provide low resistance Ohmic contact 409. A p-metal contact 423 which is typically TiAu or CrAu is provided to the p-type upper layer 421.

In one embodiment, the p-i-n junction can be reversed, such that the n-type electrode forms a contact above the layers. For a reversed p-n junction, the n-doped DBR 405 will instead be p-doped, and the p-doped upper layer 421 will be n-doped. This will form an n-i-p junction.

During growth or annealing of semiconductor layers intermixing occurs. This results in abrupt boundaries between layers of different composition becoming graded. For example, the interface between a layer of GaAs and a layer of InAs intermixes to become a graded interface that transitions from GaAs, to InGaAs, to InAs, with increasing In content as the position along the growth direction. Furthermore, intermixing of thin layers with their surrounding material may result in peak concentration less than as deposited. For example, a thin layer of InAs within GaAs would intermix so that the composition transitions smoothly between GaAs, lower indium content InGaAs, to higher indium content InGaAs, to lower indium content InGaAs, to GaAs. These effects mean that any measurement of the thickness of a layer should account for intermixing.

In an example of a method of measuring a thickness of a layer, the thickness of a layer may be determined by first measuring or estimating the composition of the layer as a function of distance along the growth axis, or growth direction, using standard STM or TEM microscopy techniques. Then, the thickness may be measured as the full-width at half-maximum of this composition profile.

The atomic nature of thin semiconductor layers means that occasional atoms of a layer material may be significantly displaced due to intermixing and diffusion. Therefore in-plane averaging may be applied over different regions of the layer to determine average values for thickness, including average values for the composition profile. For non-continuous layers, such as those perforated by quantum dots, averaging or profiling should occur only over the relevant parts of the layer.

When comparing the thickness, or maximum height of quantum dots to a layer they are in contact with, intermixing will affect the quantum dot and contacting layers similarly.

Depending on the carrier population, the injection of carriers into the quantum dot region results in the creation of excitons or multi-exciton complexes, for example, biexcitons.

An exciton is formed when there is a bound state between a small number of electrons in the conduction band and holes in the valence band, radiative decay occurring when one hole and one electron recombine resulting in the emission of a photon. Due to the atomic-like nature of quantum dots, the radiative recombination of excitons leads to the emission of single and indistinguishable photons.

The emission of entangled photon pairs can occur via the radiative biexciton cascade. The injection of two electrons and two holes into the active region with the QD leads to the formation of a biexciton (two electron-hole pairs). Under certain circumstances, the biexciton recombines radiatively emitting a pair of entangled photons. Biexcitons can be created simply by increasing the excitation power, i.e. by increasing the voltage. The biexciton state can emit “a biexciton photon” leaving one electron and one hole in a “(charge-neutral) exciton” state. This electron and hole then recombine to emit an “exciton” photon, leaving the dot empty. Through control of the properties of the exciton state these two photons can be entangled.

The light emitted from the QDs is vertically confined by the upper distributed Bragg reflector 413 and the lower distributed Bragg reflector 405. The device is designed to enhance light emission in the out of plane direction. In alternative embodiments, the optical device is an in-plane optimised device. The upper distributed Bragg reflector 413 and lower distributed Bragg reflector are reflecting structures that form a cavity structure. Such a cavity structure can be easily grown on the (100) surface of a GaAs substrate. Good quality cavities can be grown on a (100) substrate.

Distributed Bragg reflectors (DBRs) comprise in-plane periodic refractive index modulation. By selecting appropriate structures with modulation in refractive index, it is possible to control the optical mode in devices. This is advantageous for example to increase device efficiency, or reduce the photon emission time. Also, modulations in refractive index that are quasi-periodic, i.e. which deviate slightly from precise periodicity, may be used.

The structure may comprise QDs with small fine structure splitting in a good quality cavity in the presence of a quasi-wetting layer.

The presence of the wetting layer can be detected by milling a lamella and performing a cross sectional TEM or STEM measurement along the growth direction, i.e. the out of plane direction and detecting the presence of InAsP. Also, the thickness of such a layer can be used to determine what kind of dot growth technique has occurred. For Stranski-Krastanov some InAs is grown to form dots. This InAs will get blurred into InP matrix due to element V exchange but the InAs layer should still be above 1ML thick. In the droplet technique there should not be a well-defined InAs layer only a blurred InAsP layer.

Another way of determining the presence of the wetting layer is via optical detection as the wetting layer will have a lower optical excitation energy than that of the quantum dots. Excitation at an energy higher than that of the wetting layer and detection on an

InGaAs array/spectrometer can allow the determination between SK dots and droplet mode quantum dots. The thicker wetting layer formed with SK dots would be more intense and emitting at around 1100 nm (slightly higher energy than in droplet case).

The QD density in the device can be sufficiently low that an opaque mask on the top of the mesa to optically isolate single dots is not required. In other words, the density of the QDs is sufficiently low that the QDs are optically isolated from each other. For QDs that are optically isolated, exciton lines coming from an individual dot have spectra that have high signal to background ratio. In one embodiment, the signal to background ratio is greater than 10. Exciton lines coming from an individual QD are not interacting with exciton lines coming from neighbouring QDs. The optical spectrum is clean.

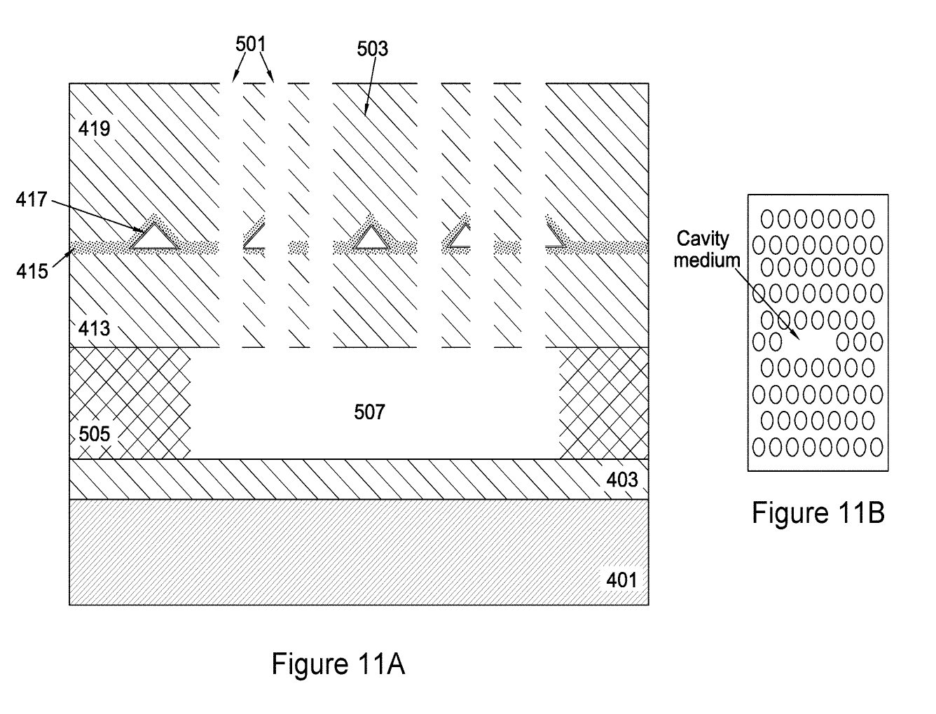

FIG. 11 is a schematic of a photonic cavity structure based on the structure of FIG. 8. To avoid any unnecessary repetition, like reference numerals will be used to denote like features. The optical cavity structure is grown on InP(100) substrate 401 followed by a 200 nm InP buffer 403 and AlInGaAs or InGaAsP sacrificial layer 505 typically 900 nm thick. Then the bottom of the cavity is grown 413 which is typically (n-½)*½ lambda thick and made of InP. The DQDs 417 are grown. Note that the 415 quasi wetting layer is formed instantly as a result of group V element exchange. The dots 417 are capped with InP 419 forming the remaining thickness of the (2n+1)*¼ lambda cavity, where n is an integer number

A plurality of holes extend through the wetting layer 415 and the upper 419 and lower 413 cavity layers in a plurality of locations, such that there are a plurality of holes 501 extending through the entire thickness of these layers. In one embodiment, the holes are cylindrical. The height of the cylindrical holes extends through the entire thickness of the wetting layer 415 and the upper 419 and lower 413 cavity layers.

In this example, the sacrificial layer is under-etched to form void 507.

The cylindrical holes are arranged as a substantially regular lattice. The photonic crystal structure is on a portion of the mesa only. In one embodiment, the cylindrical holes are arranged in a hexagonal lattice. Three adjacent holes along a line are omitted, forming a defect 503 in the lattice which is cavity region.

The periodic structure of the holes affects the propagation of light, and forms a photonic bandgap. The light emitted from a quantum dot in the slab falls within this bandgap. Specifically, the holes (which are filled with air) have a different refractive index to InP. The periodic change of materials with different refractive index means light having a wavelength within the photonic bandgap can only propagate laterally along the cavity region. The lattice structure therefore causes lateral confinement (i.e. confinement in the plane of the layers) in the cavity region of light emitted from a quantum dot 417.

A view of the photonic crystal structure from above is shown in the lower figure. The cavity medium region is the region of three omitted adjacent holes along a line. The cavity region may comprise more or less than three omitted holes. The line of holes to the right of the cavity medium region is a first reflecting structure. The line of holes to the left of the cavity medium region is a second reflecting structure, which is on the opposite side of the cavity medium region to the first reflecting structure. The regions of holes on either of the elongate sides of the cavity medium region are also reflecting structures on opposite sides of the cavity medium region.

The cavity is configured for out of plane emission. In alternative embodiments, the cavity is configured for in-plane emission.

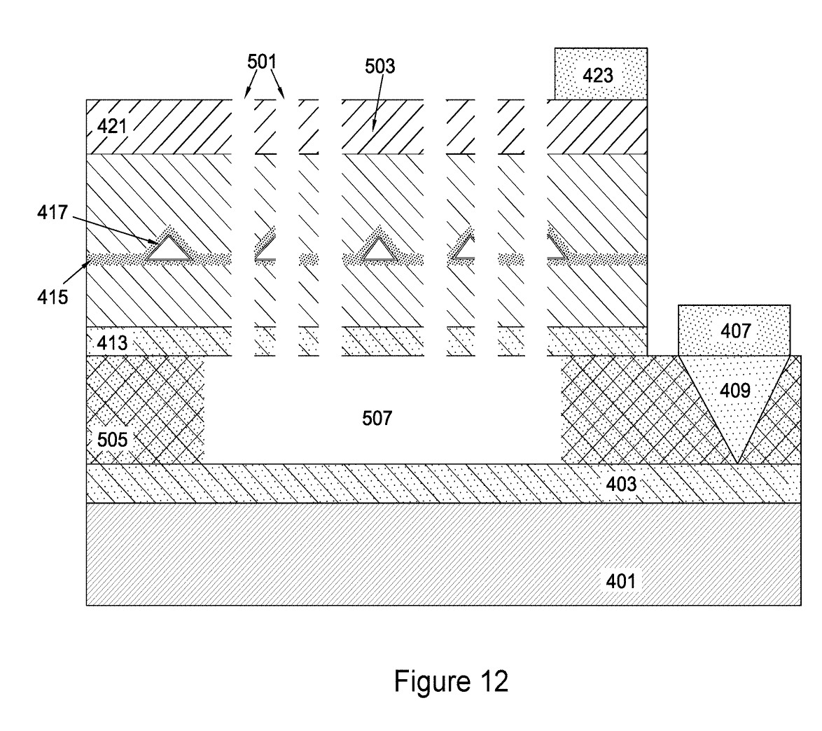

FIG. 12 is a schematic of a photonic cavity LED structure based on the structure of FIG. 8. To avoid any unnecessary repetition, like reference numerals will be used to denote like features. The optical cavity structure is grown on InP(100) substrate 401 followed by a 200 nm InP buffer 403 and AlInGaAs or InGaAsP sacrificial layer 505 typically 900 nm thick. Then the bottom of the cavity is grown 413 which is typically (n-½)*½ lambda thick and made of InP. The DQDs 417 are grown. Note that the 415 quasi wetting layer is formed instantly as a result of group V element exchange. The dots 417 are capped with InP 419 forming the remaining thickness of the (2n+1)*¼ lambda cavity, where n is an integer number. Layers 403, 505 and 413 are n-doped with Si. Layer 421 is p-doped with Zn. Although the thickness of the p-InP 421 is designed to be 50 nm the real layer is thickness is larger due to Zn diffusion into InP at high temperatures. The contacts 423 and 407 are the same as those described for FIG. 10. The formation of the photonic cavity is the same as described with reference to FIG. 11.

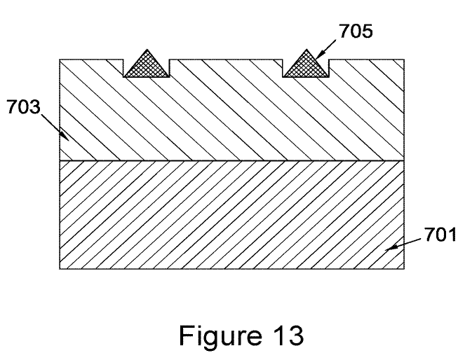

FIG. 13 is a schematic of an optical structure comprising quantum dots 705 formed by droplet epitaxy. The structure comprises a substrate 701 of InP. In the simplified structure of FIG. 13, a lower cavity layer 703 of InP is formed overlying the InP substrate 701.

In the lower cavity layer 703, 1^{st} and 2^{nd} depressions are formed. These depressions are formed using a technique such as ex-situ E-beam lithography and etching. In such a technique, once layer 703 has been formed, the partially grown structure is removed from the growth chamber and patterned and etched to form the 2 depressions.

When the structure is inserted back into the growth chamber, and MOVPE growth resumes, the indium droplets are formed preferentially in the depressions. Therefore, the droplet quantum dots 705 can be preferentially positioned.

Above, structures have been discussed which are a combination of droplet epitaxy formed within a photonic crystal structure. By using the technique described with reference to FIG. 13, it is possible to pre-position the quantum dots exactly in the centre of the defect of the photonic crystal.

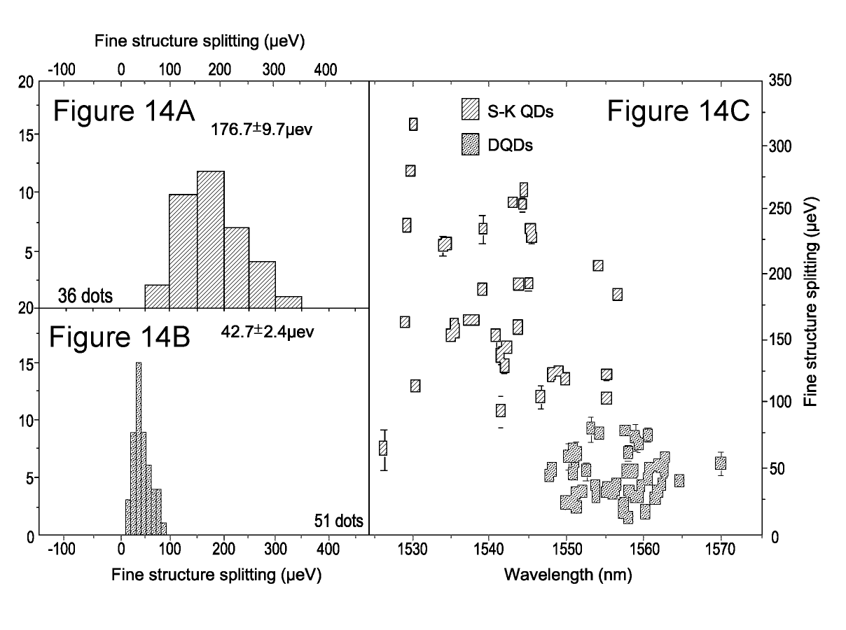

FIG. 14A is a plot of the number of quantum dots measured from a sample of 36 quantum dots against the fine structure splitting energy for the quantum dots. The results in FIG. 14A are obtained from InAs quantum dots formed on an InP layer on an InP(100) substrate using the Stranski-Krastanov growth mode. It can be seen that the main fine structure splitting is 176.7 μeV with a range of ±58.6 μeV. FIG. 14B is again a plot of the number of quantum dots against the fine structure splitting for the quantum dots. However, here, the dots are again InAs quantum dots formed on an InP substrate. However, here, the dots are formed using the droplet growth mode. It can be seen that for the 51 dots formed using droplet epitaxy, the fine structure splitting energies are considerably reduced from those produced using the strength Stranski-Krastanov growth mode.

FIG. 14C is a plot of the emitting wavelength of the quantum dots against the fine structure splitting energy for both the Stranski-Krastanov quantum dots and the droplet quantum dots. It can be seen that the droplet quantum dots have a lower fine structure splitting energy and they are also grouped in the wavelength range from 1550 to 1560 nm i.e. one of the telecom wavelength transmission ranges. The Stranski-Krastanov quantum dots have a much larger fine structure splitting energy and their emitting wavelength varies considerably.

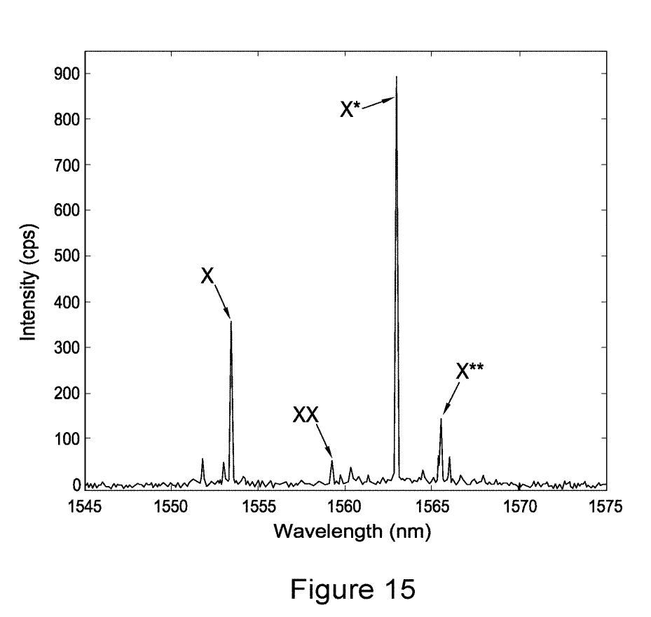

FIG. 15 is a plot of the optical response for InAs quantum dots formed on InP (100). Here, the quantum dot is optically driven. The peaks in the intensity correspond to the decay of a single neutral exciton X, a biexciton XX, a singly charged single exciton X* and a doubly charged single exciton X**.

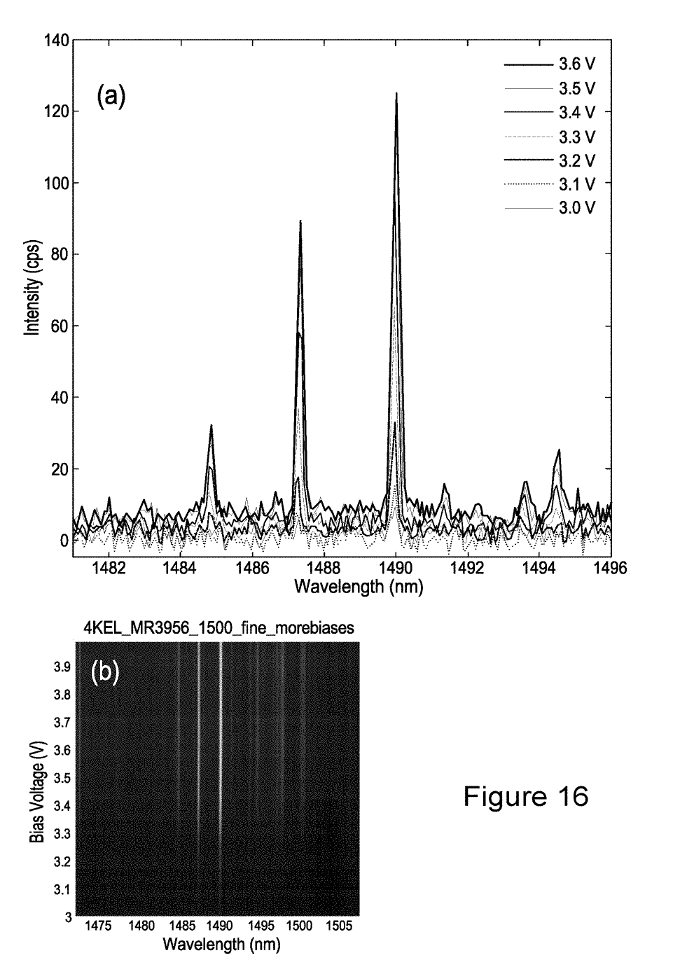

FIG. 16 is a plot of the electro-luminescence spectrum for InAs droplet quantum dots on InP (100), where (a) shows a plot of emission intensity against wavelength for 7 voltages between 3.0 V and 3.6 V incremented in 0.1 V steps. It can be seen that there are sharp peaks at 1490 nm and at approximately 1487 nm. These wavelengths are within the telecom S-band. Other dots showed emission peaks at the telecoms C-band too.

Furthermore, (b) of FIG. 16 is a plot showing essentially the same data as that of (a) but in a different representation. Here, bias voltage is plotted against wavelength on the x-axis and the intensity is plotted as a greyscale with white indicating a high intensity and black indicating a low intensity.

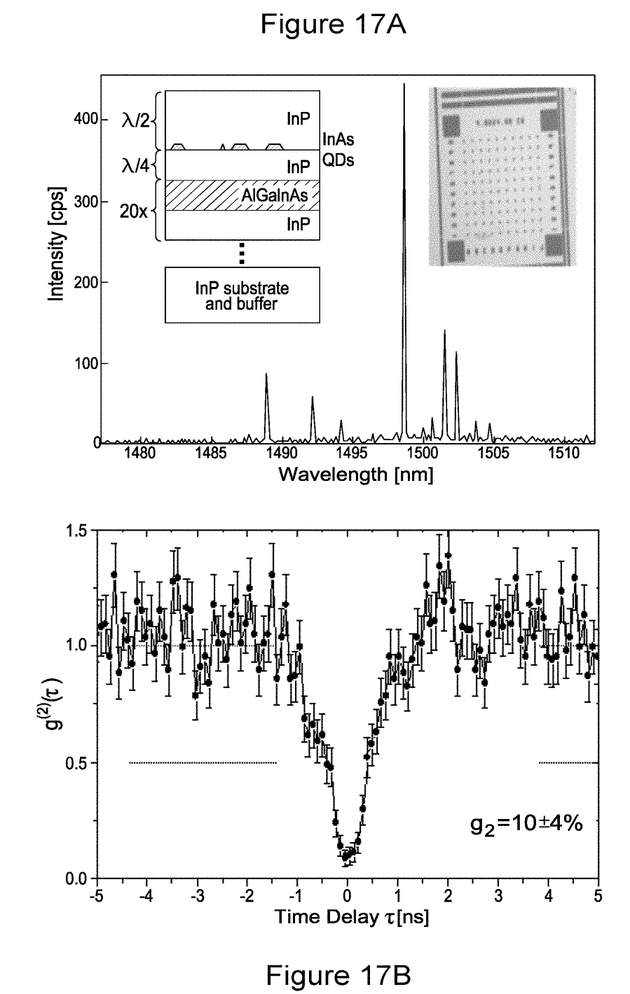

FIG. 17A is a plot of the optical response for the InAs quantum dot shown in the two pictures in the corners of the plot.

FIG. 17B is a plot showing the 2^{nd} order correlation function G2 of a droplet quantum dot produced as described above for the 2^{nd} order exciton wavelength shown in FIG. 17A.

It is clear from this measurement that a single photon source is produced as anti-bunching is clearly seen due to the dip at τ0. The value of the dip can be seen to be 10% well below the 50% threshold which is typically used to determine the presence of a single photon source.

While certain embodiments have been described, these embodiments have been presented by way of example only, and are not intended to limit the scope of the inventions. Indeed the novel methods and devices described herein may be embodied in a variety of other forms; furthermore, various omissions, substitutions and changes in the form of methods and devices described herein may be made without departing from the spirit of the inventions. The accompanying claims and their equivalents are intended to cover such forms of modifications as would fall within the scope and spirit of the inventions.

1. An optical device comprising:
a quantum dot, said quantum dot comprising InAs and adapted to emit radiation in the wavelength range from 1200 nm to 2000 nm;
a supporting layer supporting said quantum dot, said supporting layer being lattice matched to InP; and
wherein the longest dimension of the base of the quantum dot provided parallel to the supporting layer is within 20% of the shortest dimension of the base provided parallel to the supporting layer.

2. An optical device according to claim 1, wherein the fine structure splitting of the quantum dot is 50 μeV or less.

3. An optical device according to claim 1, comprising a (100) oriented substrate.

4. An optical device according to claim 1, further comprising a wetting layer provided overlying the supporting layer.

5. An optical device according to claim 4, wherein the supporting layer comprises InP or InGaAsP.

6. An optical device according to claim 5, wherein the wetting layer comprises InAsP.

7. An optical device according to claim 1, wherein the supporting layer comprises AlInAs or AlInGaAs.

8. An optical device according to claim 1, wherein an upper layer is provided overlying the quantum dot.

9. An optical device according to claim 1, comprising a plurality of quantum dots, and wherein the density of the quantum dots is less than 1×10⁹cm⁻².

10. An optical device according to claim 1, configured as an LED comprising an n doped region provided on one side of the quantum dot and a p doped region on the other side of the quantum dot.

11. An optical device according to claim 4, further comprising a filter, said filter being adapted to filter out radiation emitted by the wetting layer.

12. An optical device according to claim 1 comprising a cavity region, said cavity region adapted to accommodate said quantum dot and preferentially reflect radiation emitted from said quantum dot within said cavity.

13. An optical device according to claim 12, wherein the cavity is an asymmetric cavity comprising a single distributed Bragg reflector provided on one side of the cavity.

14. An optical device according to claim 12, wherein the cavity comprises an intrinsic region and a p-doped region is provided on one side of the quantum dot, the thickness of the layers between the quantum dot and the p-doped region being greater than the distance over which the p-type dopants diffuse into the intrinsic region at the growth temperature of the device.

15. An optical device according to claim 1, wherein the support layer is patterned and the quantum dot is positioned at point in the pattern.

16. A method of fabricating an optical device, the method comprising:
forming a support layer, said support layer being lattice matched to InP;
forming a layer of In, said amount of In being controlled to allow the formation of In droplets;
growing As over said In droplets and crystallising said droplets to form InAs dots;
wherein the formation of the In droplets and crystallisation is controlled to produce quantum dots adapted to emit radiation in the wavelength range from 1200 nm to 2000 nm and wherein the longest dimension of the base of the quantum dot provided parallel to the supporting layer is within 20% of the shortest dimension of the base provided parallel to the supporting layer.

17. A method of fabricating an optical device according to claim 16, wherein the layers are formed using MOVPE or MBE

18. A method of fabricating an optical device according to claim le wherein the structure is formed using MOVPE and 2ML of In is deposited to form the droplets.

19. A method of fabricating an optical device according to claim 16, wherein the growth temperature is raised as the As is grown over the In droplets.

20. A method of fabricating an optical device according to claim 16, wherein the droplets are capped immediately after the As is grown.
